(19) United States
(12) Patent Application Publication
(10) Pub. No.: US 2017/0332176 A1
(43) Pub. Date: Nov. 16, 2017

(54) MICROMECHANICAL COMPONENT AND METHOD FOR PACKAGING A SUBSTRATE HAVING A MICRO-ELECTROMECHANICAL MICROPHONE STRUCTURE WHICH INCLUDES AT LEAST ONE PIEZOELECTRIC LAYER

(71) Applicant: Robert Bosch GmbH, Stuttgart (DE)

(72) Inventors: Daniel Pantel, Ditzingen (DE); Fabian Purkl, Rutesheim (DE); Kerrin Doessel, Stuttgart (DE)

(21) Appl. No.: 15/585,333

(22) Filed: May 3, 2017

(30) Foreign Application Priority Data
May 13, 2016 (DE) 102016208325.2

(51) Int. Cl. H04R 17/02; H01L 41/113; H01L 41/053; H01L 41/23; H04R 1/04

(52) U.S. Cl. CPC H04R 17/02; H01L 41/23; H04R 1/04; H01L 41/0533; H01L 41/1134; H01L 41/1132; H04R 2201/003

(57) ABSTRACT

A micromechanical component having a substrate which includes a micro-electromechanical microphone structure, the micro-electromechanical microphone structure encompassing at least one piezoelectric layer and at least one polymer mass as at least part of a packaging of the substrate fitted with the micro-electromechanical microphone structure, which is in contact with at least a partial outer surface of the substrate fitted with the micro-electromechanical microphone structure. A method is also described for packaging a substrate having a micro-electromechanical microphone structure encompassing at least one piezoelectric layer by developing at least a portion of a packaging of the substrate fitted with the micro-electromechanical microphone structure from at least one polymer mass, and the at least one polymer mass being applied directly on at least a partial outer surface of the substrate fitted with the micro-electromechanical microphone structure.

### CROSS REFERENCE

The present application claims the benefit under 35 U.S.C. §119 of German Patent Application No. DE 102016208325.2 filed on May 13, 2016, which is expressly incorporated herein by reference in its entirety.

### FIELD

The present invention relates to a micromechanical component and to a microphone. In addition, the present invention relates to a method for packaging a substrate having a micro-electromechanical microphone structure including at least one piezoelectric layer.

### BACKGROUND INFORMATION

A piezoelectric microphone, which has a multitude of bending beams, is described in U.S. Patent Appl. Pub. No. 2014/0339657 A1. Each bending beam is made up of a first electrode, which is made from molybdenum and is anchored on a substrate; a first piezoelectric layer of aluminum nitride which at least partially covers the first electrode; a second electrode of molybdenum, which covers the first piezoelectric layer; a second piezoelectric layer of aluminum nitride covering the second electrode; and a third electrode of molybdenum covering the second piezoelectric layer.

### SUMMARY

The present invention provides a micromechanical component, a microphone, and a method for packaging a substrate having a micro-electromechanical microphone structure, which includes at least one piezoelectric layer.

Example embodiment of the present invention provide more advantageous and cost-effective options for packaging a substrate having a micro-electromechanical microphone structure that includes at least one piezoelectric layer. In this context, the improved robustness of such a micro-electromechanical microphone structure (in particular in comparison with a capacitive micro-electromechanical microphone structure) with regard to mechanical stress that occurs in the at least one polymer mass, is utilized by the present invention for the realization of smaller and less expensive packages.

While relatively resource-intensive packaging is conventionally used for substrates having at least one micro-electromechanical microphone structure, e.g., a cover that freely arches over the respective substrate and is mounted on a carrier fitted with the substrate, the present invention provides packaging that is able to be produced more easily and cheaply with the aid of the at least one polymer mass. The conventional cover, which is typically made of metal, has to have a significant clearance from the substrate over which it arches (due to process tolerances when bonding the cover to the carrier) and will typically be attached to the carrier in a separate process. As a result, it is hardly possible to minimize the conventional cover and the carrier that interacts with the cover. As described in greater detail in the following text, the packaging of the substrate fitted with the micro-electromechanical microphone structure that is realizable with the aid of the present invention is able to be produced in a rapid manner and by an easily executable method step. This not only makes it possible to utilize the advantageous robustness of the micro-electromechanical microphone structure with regard to particles and fluids, but also to use its low stress sensitivity for minimizing the micromechanical component and for lowering its production costs.

When referring to the at least one piezoelectric layer, a material layer is described, which has a charge/voltage at its oppositely oriented surfaces when subjected to a mechanical force or to mechanical stress. Examples of a piezoelectric material of the at least one piezoelectric layer particularly are aluminum nitride (AlN), zinc oxide (ZnO), and lead zirconate titanate (PZT). However, it is pointed out that the ability to develop the at least one piezoelectric layer is not restricted to the use of the materials described here.

For example, the at least one polymer mass may be, or may include, a gel, a molding mass, an underfill material and/or a glob top material. Thus, it is possible to use more cost-effective and more easily processable materials for the present invention.

In particular, the micro-electromechanical microphone structure may include at least one bending-beam substructure, which encompasses the respective at least one piezoelectric layer. Such a bending-beam substructure is less sensitive to stress than a diaphragm, and is therefore better suited for the packaging according to the present invention with the aid of the at least one polymer mass.

In an advantageous specific embodiment of the micromechanical component, the micro-electromechanical microphone structure includes a first outer electrode, a second outer electrode, an intermediate electrode situated between the first outer electrode and the second outer electrode, and a first piezoelectric layer and a second piezoelectric layer as the at least one piezoelectric layer. A first intermediate volume between the first outer electrode and the intermediate electrode is at least partially filled with the first piezoelectric layer, and a second intermediate volume between the intermediate electrode and the second outer electrode is at least partially filled with the second piezoelectric layer. As a result, the micro-electromechanical microphone structure may have a relatively simple design and is therefore easily able to be developed on the substrate. In addition, such a micro-electromechanical microphone structure has an advantageous robustness with regard to mechanical stress and may therefore be packaged to good effect using the at least one polymer mass, which contacts at least the partial outer surface of the substrate fitted with the micro-electromechanical microphone structure.

Preferably, at least an edge region of the micro-electromechanical microphone structure is anchored on the substrate while at least one self-supporting area of the micro-electromechanical microphone structure at least partially spans a cavity or recess developed in the substrate. The micro-electromechanical microphone structure is thus well suited for executing a microphone function.

In another advantageous specific embodiment of the micromechanical component, the substrate fitted with the micro-electromechanical microphone structure is attached, either directly or indirectly, to a carrier side of a carrier, and the at least one polymer mass covers the carrier side of the carrier over at least part of its surface. The substrate fitted with the micro-electromechanical microphone structure may also be attached to the carrier side of the carrier via an interposer or an intermediate substrate. Attaching the conventional cover to the carrier with the aid of an individual process or a batch process from the related art is therefore not necessary in order to cover the carrier side fitted with the substrate.

A first depression may possibly be developed adjacent to the micro-electromechanical microphone structure in the carrier side of the carrier. In the same way, a second depression or an uninterrupted recess may be developed adjacent to the micro-electromechanical microphone structure in the interposer or in the intermediate substrate. It is therefore still possible to provide a sufficient volume (back volume) for excellent acoustics of the micro-electromechanical microphone structure even if the entire micromechanical component has a relatively small design. (A back volume that is too small may acoustically act like a spring and may thus reduce the deflection.)

For example, a maximum height of the at least one polymer mass perpendicular to the carrier side of the carrier may at least be greater than a distance of the substrate from the carrier side of the carrier. In particular, the maximum height of the at least one polymer mass perpendicular to the carrier side of the carrier may be greater than or equal to a sum of a height of the substrate perpendicular to the carrier side of the carrier and the distance of the substrate from the carrier side of the carrier. The substrate fitted with the micro-electromechanical microphone structure may thus be easily embedded into the at least one polymer mass to such a depth that only an active side of the micro-electromechanical microphone structure is freely exposed.

In an advantageous further refinement of the micromechanical component, a depression framing the substrate fitted with the micro-electromechanical microphone structure is developed in a surface that is pointing away from the carrier side of the carrier and is formed by the at least one polymer mass. The depression is able to be used for the reliable insertion of a sealing ring so that the part of the packaging developed from the at least one polymer mass is able to form a fluid-tight and/or air-tight, and especially an acoustically tight, package together with other package components.

The advantages described above may be likewise provided in a microphone having such a micromechanical component.

In addition, the execution of a corresponding method for packaging a substrate having a micro-electromechanical microphone structure that includes at least one piezoelectric layer also provides the afore-described advantages. It is expressly pointed out that the method according to the afore-described specific embodiments of the micromechanical component is able to be further refined.

### BRIEF DESCRIPTION OF THE DRAWINGS

Additional features and advantages of the present invention will be described in the following text on the basis of the figures.

FIG. 1 through 11 show schematic representations of specific embodiments of the micromechanical component.

FIG. 12 shows a flow diagram to elucidate a specific embodiment of the method for packaging a substrate having a micro-electromechanical microphone structure that includes at least one piezoelectric layer.

### DETAILED DESCRIPTION OF EXAMPLE EMBODIMENTS

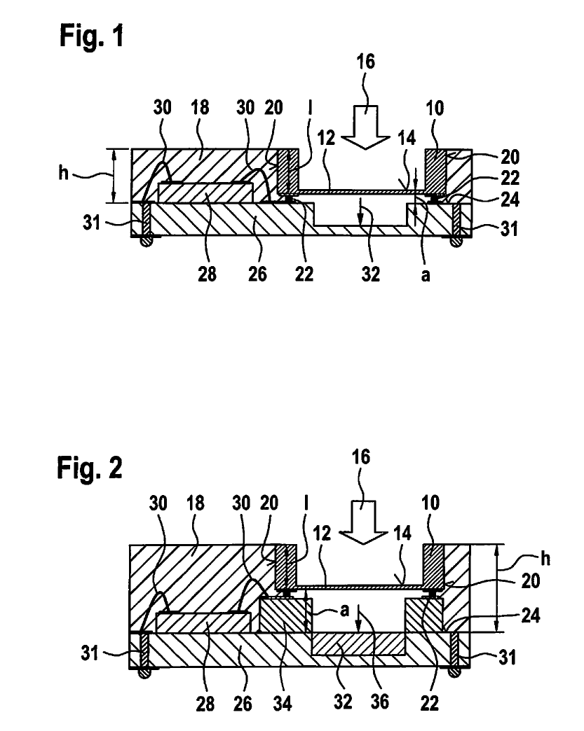

FIG. 1 shows a schematic representation of a first specific embodiment of the micromechanical component.

The micromechanical component schematically shown in FIG. 1 includes a substrate 10 (e.g., a chip), which may at least partially be developed from at least one semiconductor material such as silicon, in particular. However, substrate 10 may also include at least one metal and/or at least one insulating material. It is pointed out that a producibility of the micromechanical component described in the following text is not limited to a particular material for substrate 10. Substrate 10 has a micro-electromechanical microphone structure 12, which encompasses at least one piezoelectric layer (not sketched). For this reason, micro-electromechanical microphone structure 12 may also be referred to as a piezoelectric microphone structure. Micro-electromechanical microphone structure 12 has an exposed active side 14 (sound-receiving side), on which sound waves 16 may impinge. Sound waves 16 impinging upon active side 14 induce a mechanical deformation/bending of parts of micro-electromechanical microphone structure 12 and thus, an electrical voltage in the at least one piezoelectric layer, thereby making it possible to detect sound waves 16 with the aid of an output voltage. Merely by way of example, micro-electromechanical microphone structure 12 is developed on a side of substrate 10 that is pointing away from the (likely) sound source.

The micromechanical component of FIG. 1 also includes at least one polymer mass 18 as at least part of a packaging of substrate 10 fitted/developed with micro-electromechanical microphone structure 12. The at least one polymer mass 18 is deposited in such a way that the at least one polymer mass 18 is in (direct) contact with at least a partial outer surface 20 of substrate 10 fitted/developed with micro-electromechanical microphone structure 12. The packaging realized with the aid of the at least one polymer mass 18 thus utilizes the advantageous robustness of micro-electromechanical microphone structure 12, developed to include the at least one piezoelectric layer, with regard to mechanical stress that occurs during a thermal expansion of the at least one polymer mass 18, for example. (As a rule, the at least one polymer mass 18 has a higher coefficient of thermal expansion than the at least one material of substrate 10.) While in the case of a conventional capacitive micro-electromechanical microphone structure, a thermal expansion of the at least one polymer mass 18 that is in (direct) contact with the substrate provided therewith would have a detrimental effect its functioning, the functioning of the micro-electromechanical microphone structure is fully retained despite the thermal expansion of the at least one polymer mass 18. The (direct) contact between the at least one partial outer surface 20 of substrate 10 (fitted/developed with micro-electromechanical microphone structure 12) and the at least one polymer mass 18 is therefore without disadvantages, and the small and cost-effective options for packaging substrate 10 that are realizable with the aid of the at least one polymer mass 18 are able to be utilized.

In the specific embodiment of FIG. 1, substrate 10 fitted/developed with micro-electromechanical microphone structure 12 is attached to a carrier side 24 of a carrier 26. For example, at least one flip chip connection (bump connection, stud-bump connection, soldered connection) 22 and/or at least one bond connection (wafer bond connection) may be developed between substrate 10 and carrier side 24 of carrier 26. In particular, the at least one flip chip connection 22 and/or bond connection may have a tightness such that the at least one polymer mass 18 is prevented from entering a volume framed by respective flip chip connection 22 and/or bond connection. Carrier 26, for example, may be a circuit board or an interposer. It is pointed out that a producibility of the micromechanical component is not restricted to a certain carrier type of carrier 26.

In addition to substrate 10 fitted/developed with micro-electromechanical microphone structure 12, at least one further semiconductor device 28 such as an application-specific integrated circuit (ASIC) may optionally be attached to carrier side 24 of carrier 26 (e.g., via at least one flip chip connection and/or bond connection). Moreover, further semiconductor device 28 may be electrically linked to carrier 26 by way of at least one electrical connection 30 such as via at least one wire connection 30, for example, in particular to at least one through-connection 31 developed in carrier 26. The at least one electrical connection/wire connection 30 may be surrounded by a respective dielectric sheath in order to improve an electrical insulation of the at least one electrical connection/wire connection 30, so as to prevent parasitic effects or to avoid ageing processes.

The at least one polymer mass 18 covers carrier side 24 of carrier 26 over at least parts of its surface. The at least one polymer mass 18 may thereby be utilized for protecting the at least one flip chip connection 22 and/or bond connection between substrate 10 and carrier side 24; the at least one flip chip connection and/or bond connection between additional semiconductor device 28 and carrier side 24; and/or the at least one electrical connection 30. In particular, a maximum height h of the at least one polymer mass 18 perpendicular to carrier side 24 of carrier 26 may be greater than or equal to a sum of a height/length | of substrate 10 (perpendicular to carrier side 24 of carrier 26) and a distance a of substrate 10 from carrier side 24 or carrier 26. All components attached to/developed on carrier side 24 of carrier 26 may therefore be embedded in the at least one polymer mass 18 to such a depth that (nearly) only active side 14 of micro-electromechanical microphone structure 12 remains exposed.

Optionally, a depression 32 may also be developed adjacent to micro-electromechanical microphone structure 12 in carrier side 24 of carrier 26. Depression 32 ensures a volume of sufficient size (back volume) for excellent acoustics of micro-electromechanical microphone structure 12.

FIG. 2 shows a schematic representation of a second specific embodiment of the micromechanical component.

As a further refinement to that of FIG. 1, in this specific embodiment, substrate 10 fitted with micro-electromechanical microphone structure 12 is attached to carrier side 24 of carrier 26 with the aid of an interposer 34. (In the specific embodiment of FIG. 2, substrate 10 is exemplarily fastened to interposer 34 via the at least one flip chip connection 22 and/or bond connection.) Interposer 34, for example, may be a circuit board (printed circuit board PCP) or be made of glass. Optionally, a depression or an uninterrupted recess 36 may be developed adjacent to micro-electromechanical microphone structure 12 in interposer 34. This, too, ensures a sufficient volume (back volume) for excellent acoustics of micro-electromechanical microphone structure 12. As an alternative to interposer 34, another semiconductor device (such as an application-specific integrated circuit) and/or an intermediate substrate may also lie between substrate 10 fitted/developed with micro-electromechanical microphone structure 12 and carrier side 24 of carrier 26.

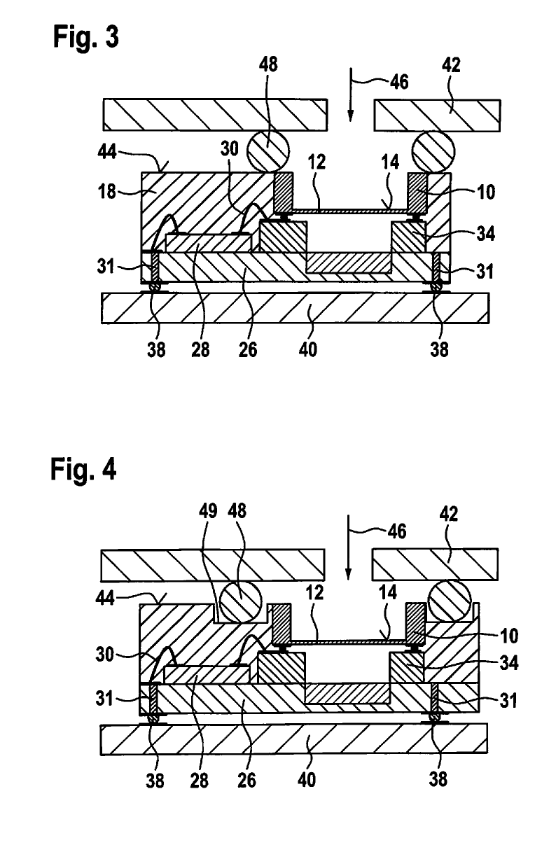

FIG. 3 shows a schematic representation of a third specific embodiment of the micromechanical component.

The micromechanical component of FIG. 3 is a further refinement of the previously described specific embodiment. In supplementation, the previously described specific embodiment is placed inside a housing (such as the housing of a mobile telephone).

Carrier 26 is attached (e.g., via at least one flip chip connection 38 and/or bond connection and/or soldered connection) to a carrier board 40 (such as a circuit board). In addition, a cover 42 such as the housing of a mobile telephone, spans a surface 44 which is pointing away from carrier side 24 of carrier 26 and is formed by the at least one polymer mass 18. Preferably, cover 42 has a sound opening 46, which lies adjacent to active side 16 of micro-electromechanical microphone structure 12. Preferably, sound opening 46 terminates in a volume framed by a sealing ring 48, sealing ring 48 being inserted/mounted between surface 44, formed by the at least one polymer mass 18, and an inner side of cover 42.

FIG. 4 shows a schematic representation of a fourth specific embodiment of the micromechanical component.

In contrast to the previously described specific embodiment, in the micromechanical component of FIG. 4, a depression 49 that frames substrate 10 (fitted/developed with micro-electromechanical microphone structure 12) is developed in surface 44 that is pointing away from carrier side 24 of carrier 46 and formed by the at least one polymer mass 18. Installing sealing ring 48 in depression 49 prevents the sealing ring from slipping while the micromechanical component is in use.

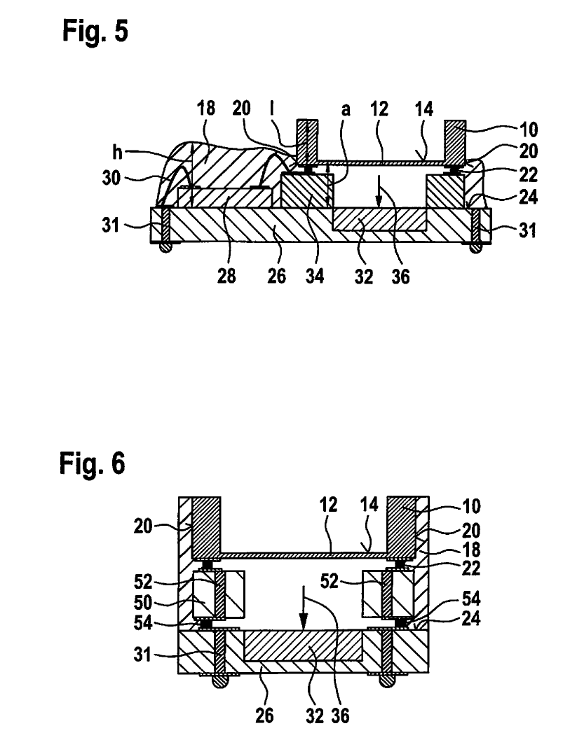

FIG. 5 shows a schematic representation of a fifth specific embodiment of the micromechanical component.

The micromechanical component of FIG. 5 differs from the specific embodiment of FIG. 2 in that maximum height h of the at least one polymer mass 18 (perpendicular to carrier side 24 of carrier 26) is indeed greater than distance a of substrate 10 from carrier side 24 of carrier 26 but smaller than the sum of height/length | of substrate 10 (perpendicular to carrier side 24 of carrier 26) and distance a of substrate 10 from carrier side 24 of carrier 26.

FIG. 6 shows a schematic representation of a sixth specific embodiment of the micromechanical component.

In the specific embodiment of FIG. 6, substrate 10, fitted/developed with micro-electromechanical microphone 12, is connected via an intermediate substrate 50 to carrier 26. Intermediate substrate 50 is attached to carrier side 24 of carrier 26 either directly or by way of at least one flip chip connection 54 and/or bond connection. In particular, at least one through-connection 52 may be developed in intermediate substrate 50, which is connected to the at least one through-connection 31 of carrier 26.

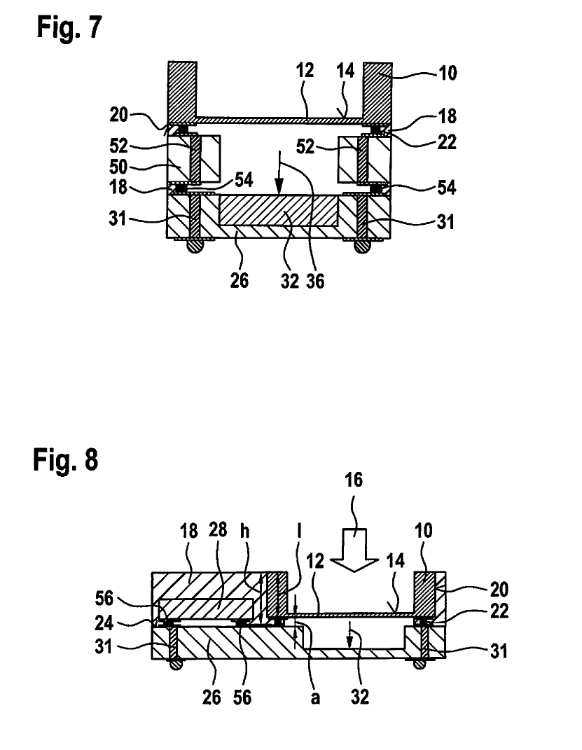

FIG. 7 shows a schematic representation of a seventh specific embodiment of the micromechanical component.

The micromechanical component from FIG. 7 differs from the previously described specific embodiment in that the at least one polymer mass 18 is filled only into the intermediate gap between components 10 and 50 and between components 26 and 50.

FIG. 8 shows a schematic representation of an eighth specific embodiment of the micromechanical component.

In the specific embodiment of FIG. 8, substrate 10 is attached to a carrier 26, developed as an interposer, via at least one flip chip connection 22 and/or bond connection. In this case as well, carrier 26 developed as an interposer is preferably a circuit board or made of glass. In addition, further semiconductor device 28 is fastened to carrier side 24 of carrier 26 via at least one flip chip connection 56 and/or bond connection.

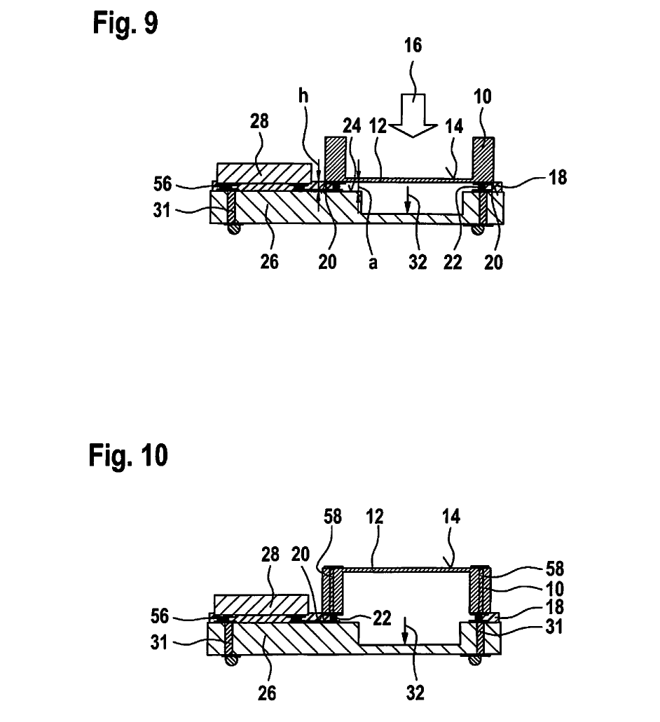

FIG. 9 shows a schematic representation of a ninth specific embodiment of the micromechanical component.

In a variation of the previously described specific embodiment, in the micromechanical component of FIG. 9, the at least one polymer mass 18 is deposited on carrier side 24 only up to a maximum height h (perpendicular to carrier side 24 of carrier 26), which is slightly greater than distance a of substrate 10 from carrier side 24 of carrier 26. This, too, ensures reliable protection of flip chip connections 22 and 56 and/or bond connections.

FIG. 10 shows a schematic illustration of a tenth specific embodiment of the micromechanical component.

In the specific embodiment of FIG. 10, micro-electromechanical microphone structure 12 is developed on a side of substrate 10 that is pointing toward the (probable) sound source (or away from carrier 26). However, an electrical connection of micro-electromechanical microphone structure 12 to carrier 26 (or to additional semiconductor device 28 developed as an application-specific integrated circuit) is easily realizable via at least one through-connection 58 (through silicon via TSV) through substrate 10. Therefore, an underfill of substrate 10 using the at least one polymer mass 18 up to a maximum height h (perpendicular to carrier side 24 of carrier 26), which is only slightly larger than distance a of substrate 10 from carrier side 24 of carrier 26, is sufficient.

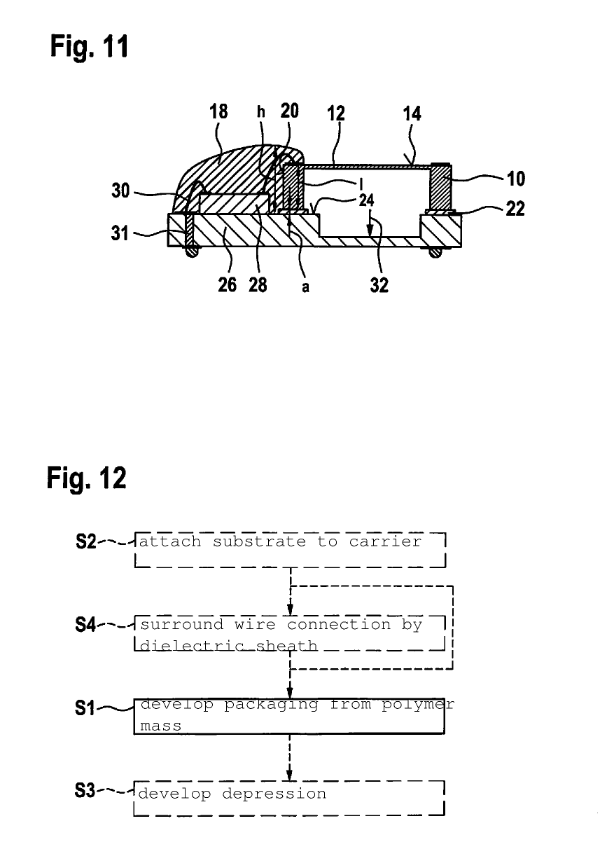

FIG. 11 shows a schematic representation of an eleventh specific embodiment of the micromechanical component.

In the specific embodiment of FIG. 11, an electrical connection of micro-electromechanical microphone structure 12 to additional semiconductor device 28 implemented as an application-specific integrated circuit takes place via at least one wire connection 60, which extends between a side of additional semiconductor device 28 pointing away from carrier 26 and a side of substrate 10 pointing away from carrier 26. A reliable protection of the at least one wire connection 60 is easily able to be ensured in that the at least one polymer mass 18 is deposited at a maximum height h that is greater than the sum of height/length | of substrate 10 (perpendicular to carrier side 24 of carrier 26) and distance a of substrate 10 from carrier side 24 of carrier 26.

All specific embodiments described above may be developed with a small overall volume. In particular, the micro-electromechanical microphone structure in each of the afore-described specific embodiments may include a first outer electrode, a second outer electrode, an intermediate electrode situated between the first outer electrode and the second outer electrode, and a first piezoelectric layer and a second piezoelectric layer as the at least one piezoelectric layer. A first intermediate volume between the first outer electrode and the intermediate electrode is at least partially filled with the first piezoelectric layer, and a second intermediate volume between the intermediate electrode and the second outer electrode is at least partially filled with the second piezoelectric layer. In the same way, the micro-electromechanical microphone structure may have at least one bending-beam substructure which in each case includes at least the first outer electrode, the first piezoelectric layer, the intermediate electrode, the second piezoelectric layer and the second outer electrode. Preferably, at least one edge region of the micro-electromechanical microphone structure is anchored on the substrate while at least one self-supporting area of the micro-electromechanical microphone structure at least partially spans a cavity or recess developed in the substrate.

In the afore-described specific embodiments, the at least one polymer mass 18 may be, or may include, a gel, a molding mass, an underfill material and/or a glob top material. However, it is pointed out that a producibility of the micromechanical components is not restricted to the use of a specific polymer material.

FIG. 12 shows a flow diagram to explain a specific embodiment of the method for packaging a substrate having a micro-electromechanical microphone structure which includes at least one piezoelectric layer.

The present method includes at least one method step S1 in which at least a portion of a packaging of the substrate fitted with the micro-electromechanical microphone structure is developed from at least one polymer mass. To do so, the at least one polymer mass is applied directly onto at least a partial outer surface of the substrate fitted with the micro-electromechanical microphone structure. An active side (sound-receiving side), on which sound waves may impinge during an operation of the later micro-electromechanical microphone structure, remains uncovered by the at least one polymer mass or will be exposed from the at least one polymer mass following method step S1. The active side may be protected, especially while the at least one polymer mass is deposited, with the aid of a (flexible) stamp, a foil or an (easily removable) polymer material such as with the aid of a thermally decomposable polymer material.

The at least one polymer mass is able to be applied via an injection process (injection molding), for example, or via a dispensing process. In particular, the at least one polymer mass may be/include a gel, a molding mass, an underfill material, and/or a glob top material. It is pointed out that an executability of the method described here is not restricted to the use of a specific polymer material.

In an optional method step S2, which is able to be carried out prior to developing the packaging (i.e. prior to method step S1), the substrate fitted with the micro-electromechanical microphone structure is attached directly or indirectly to a carrier side of a carrier. The substrate fitted/developed with the micro-electromechanical microphone structure, for example, is able to be attached/bonded to the carrier or to an intermediate component such as especially an interposer, via a flip chip assembly/a flip chip process, for instance. At least one flip chip connection (bump connection, stud-bump connection, solder connection), for example, and/or at least one bonding connection (wafer bonding connection) is/are formed between the substrate and the carrier/intermediate component. At least one electrical connection, in particular a wire connection, is also able to be developed between the substrate/a further semiconductor device and the carrier/intermediate component. Subsequently, the carrier side of the carrier is able to be covered across at least part of the surface with the at least one polymer mass in method step S1. Preferably, the at least one polymer mass is deposited up to a maximum height (perpendicular to the carrier side of the carrier) of at least a distance of the substrate fitted with the micro-electromechanical microphone structure from the carrier side of the carrier.

For example, the at least one polymer mass is able to be deposited up to a maximum height (perpendicular to the carrier side of the carrier) that is greater than or equal to a sum of a height/length of the substrate (perpendicular to the carrier side of the carrier) and the distance of the substrate fitted with the micro-electromechanical microphone structure from the carrier side of the carrier. In an optional method step S3, a depression, which frames the substrate (fitted with the micro-electromechanical microphone structure), is subsequently able to be developed in a surface that is pointing away from the carrier side of the carrier and that is developed from the at least one polymer mass, the depression later ensuring a reliable hold for a sealing ring introduced therein.

In a further optional method step S4, which is likewise able to be carried out prior to developing the packaging (i.e. prior to method step S1), the at least one electrical connection, in particular the at least one wire connection, is surrounded by a dielectric sheath (prior to applying the at least one polymer mass) in order to improve an electrical insulation of the at least one electrical connection/wire connection, to restrict parasitic effects, or to prevent ageing processes. The at least one dielectric sheath, for example, is able to be applied with the aid of an atomic layer deposition (ALD).

What is claimed is:

1. A micromechanical component, comprising:
a substrate which has a micro-electromechanical microphone structure, the micro-electromechanical microphone structure including at least one piezoelectric layer; and
at least one polymer mass which is at least part of a packaging of the substrate fitted with the micro-electromechanical microphone structure, the polymer mass being in contact with at least a partial outer surface of the substrate fitted with the micro-electromechanical microphone structure.

2. The micromechanical component as recited in claim 1, wherein the micro-electromechanical microphone structure has at least one bending-beam substructure which includes at least the at least one piezoelectric layer in each case.

3. The micromechanical component as recited in claim 1, wherein the micro-electromechanical microphone structure has a first outer electrode, a second outer electrode, an intermediate electrode disposed between the first outer electrode and the second outer electrode, and a first piezoelectric layer and a second piezoelectric layer as the at least one piezoelectric layer, and a first intermediate volume between the first outer electrode and the intermediate electrode is at least partially filled with the first piezoelectric layer, and a second intermediate volume between the intermediate electrode and the second outer electrode is at least partially filled with the second piezoelectric layer.

4. The micromechanical component as recited in claim 1, wherein at least an edge region of the micro-electromechanical microphone structure is anchored on the substrate while at least one self-supporting area of the micro-electromechanical microphone structure at least partially spans one of a cavity or a recess in the substrate.

5. The micromechanical component as recited in claim 1, wherein the substrate fitted with the micro-electromechanical microphone structure is directly or indirectly attached to a carrier side of a carrier, and the carrier side of the carrier is covered by the at least one polymer mass at least over part of the surface.

6. The micromechanical component as recited in claim 5, wherein a first depression is developed adjacent to the micro-electromechanical microphone structure in the carrier side of the carrier.

7. The micromechanical component as recited in claim 5, wherein the substrate fitted with the micro-electromechanical microphone structure is attached to the carrier side of the carrier via one of an interposer or an intermediate substrate, and wherein one of a second depression or an uninterrupted recess is developed adjacent to the micro-electromechanical microphone structure in the interposer or in the intermediate substrate.

8. The micromechanical component as recited in claim 5, wherein a maximum height of the at least one polymer mass perpendicular to the carrier side of the carrier is at least greater than a distance of the substrate from the carrier side of the carrier.

9. The micromechanical component as recited in claim 8, wherein the maximum height of the at least one polymer mass perpendicular to the carrier side of the carrier is greater than or equal to a sum of a height of the substrate perpendicular to the carrier side of the carrier and the distance of the substrate from the carrier side of the carrier.

10. The micromechanical component as recited in claim 9, wherein a depression, which frames the substrate fitted with the micro-electromechanical microphone structure, is developed in a surface that is pointing away from the carrier side of the carrier and is formed by the at least one polymer mass.

11. A microphone having a micromechanical component, the micromechanical component including a substrate which has a micro-electromechanical microphone structure, the micro-electromechanical microphone structure including at least one piezoelectric layer; and at least one polymer mass which is at least part of a packaging of the substrate fitted with the micro-electromechanical microphone structure, the polymer mass being in contact with at least a partial outer surface of the substrate fitted with the micro-electromechanical microphone structure.

12. A method for packaging a substrate having a micro-electromechanical microphone structure which includes at least one piezoelectric layer, the method comprising:
developing at least a portion of a packaging of the substrate fitted with the micro-electromechanical microphone structure from at least one polymer mass, the at least one polymer mass being applied directly on at least a partial outer surface of the substrate fitted with the micro-electromechanical microphone structure.

13. The method as recited in claim 12, wherein, prior to developing the packaging, the substrate fitted with the micro-electromechanical microphone structure is attached directly or indirectly to a carrier side of a carrier, whereupon the carrier side of the carrier is covered by the at least one polymer mass over at least part of its surface, the at least one polymer mass being deposited up to a maximum height perpendicular to the carrier side of the carrier of at least a distance of the substrate from the carrier side of the carrier.

14. The method as recited in claim 13, wherein the at least one polymer mass is deposited up to a maximum height perpendicular to the carrier side of the carrier greater than or equal to a sum of a height of the substrate perpendicular to the carrier side of the carrier and the distance of the substrate from the carrier side of the carrier, and a depression that frames the substrate fitted with the micro-electromechanical microphone structure is developed in a surface that is pointing away from the carrier side of the carrier and is formed by the at least one polymer mass.

15. The method as recited in claim 12, wherein at least one electrical connection is surrounded by a respective dielectric sheath prior to the application of the at least one polymer mass.
